(19) United States
(12) Patent Application Publication
(10) Pub. No.: US 2024/0102154 A1
(43) Pub. Date: Mar. 28, 2024

(54) VACUUM PROCESSING APPARATUS, VACUUM SYSTEM, GAS PARTIAL PRESSURE CONTROL ASSEMBLY, AND METHOD OF CONTROLLING PARTIAL PRESSURE OF A GAS IN A VACUUM PROCESSING CHAMBER

(71) Applicant: Applied Materials, Inc., Santa Clara, CA (US)

(72) Inventors: Chun Cheng CHEN, Kaohsiung City (TW); Hung-Wen CHANG, New Taipei City (TW); Shin-Hung LIN, Tainan City (TW); Chi-Chang YANG, Tainan (TW); Christoph MUNDORF, Freigericht (DE); Thomas GEBELE, Freigericht (DE); Jürgen GRILLMAYER, Chiayi (TW)

(21) Appl. No.: 17/768,799

(22) PCT Filed: Feb. 24, 2020
(86) PCT No.: PCT/EP2020/054782

§ 371 Date: Apr. 13, 2022

(51) Int. Cl. C23C 14/54; C23C 14/24; C23C 14/56

(52) U.S. Cl. CPC C23C 14/542; C23C 14/24; C23C 14/566

(57) ABSTRACT

A vacuum processing apparatus (110) for deposition of a material on a substrate is provided. The vacuum processing apparatus (110) includes a vacuum chamber comprising a processing area (111); a deposition apparatus (112) within the processing area (111) of the vacuum chamber; a cooling surface (113) inside the vacuum chamber; and one or more movable shields (220) between the cooling surface (113) and the processing area (111).

### FIELD

Embodiments of the present disclosure relate to a vacuum processing apparatus for deposition of a material on a substrate and a method for maintaining gas partial pressure, for example, partial water vapor pressure, inside the vacuum processing apparatus while depositing a material on a substrate. Particularly, embodiments relate to control and/or adjustment of partial pressures in a deposition area of a vacuum processing apparatus, such as a physical vapor deposition (PVD) apparatus.

### BACKGROUND

There are several techniques for layer deposition on a substrate, for example, sputter deposition, physical vapor deposition (PVD), chemical vapor deposition (CVD), thermal evaporation and spin coating. Coated substrates may be used in several applications and in several technical fields. For instance, coated substrates may be used for the manufacture of electronic devices on wafers or for the manufacture of display devices. Display devices can be used in the manufacture of television screens, computer monitors, mobile phones, other hand-held devices, and the like for displaying information. Typically, displays are produced by coating a substrate with a stack of layers of different materials.

In order to deposit a layer stack on a substrate, an arrangement of processing modules can be used. The processing of the substrate may be conducted under sub atmospheric pressure in a vacuum chamber. Control of the process conditions such as partial pressures of the process gas(es) influences the deposition process.

Different layer stack concepts are used in processing substrates. The layer stack concepts may also include for example a layer stack with transparent insulating layers and a TCO layer, e.g. an indium tin oxide (ITO) layer. For example, in the display industry, layers including a transparent conductive oxide (e.g. ITO), metals (e.g. Mo, Al), and active layers (e.g. IGZO) are coated onto substrates.

Together with the fast-paced technological evolution, the quality of deposition and sputtering is intended to be improved. Physical vapor deposition processes (PVD), such as sputtering, may show a process drift due to changing partial gas pressure, for example, changing water vapor partial pressure. This may be resolved by pre-sputtering or preventative maintenance.

The substrate may be carried through the vacuum system by a carrier. The carrier carrying the substrate is typically transported through a vacuum system using a transport system. A carrier supporting a substrate, such as a large area substrate during deposition, may be subject to material deposition on the carrier. In the vacuum processing apparatuses, along with the tool operation time, the amount of materials coated on the carrier increases the probability of carriers to capture moisture. Therefore, for moisture sensitive processes, an intermediate pre-sputter measure or frequent preventative maintenance are beneficial to prevent process drift.

For example, it has been shown that there is a dependency between the crystallization temperature and a water vapor partial pressure. The films deposited at low water vapor pressures exhibited preferred orientation, whereas those deposited at high water vapor pressures didn't exhibit preferred orientation.

Accordingly, control of partial pressure of gases, such as water vapor, can improve deposition of thin films on a substrate.

### SUMMARY

In light of the above, a vacuum processing apparatus for deposition of a material on a substrate and a gas partial pressure control assembly for a vacuum processing apparatus and a method of controlling gas partial pressure in a vacuum processing apparatus are provided. Further aspects, benefits, and features of the present disclosure are apparent from the claims, the description, and the accompanying drawings.

According to an aspect of the present disclosure, a vacuum processing apparatus for deposition of a material on a substrate is provided. The vacuum processing apparatus includes a vacuum chamber comprising a processing area; a deposition apparatus within the processing area of the vacuum chamber; a cooling surface inside the vacuum chamber; and one or more movable shields between the cooling surface and the processing area.

According to another aspect of the present disclosure, a gas partial pressure control assembly for a vacuum processing chamber is provided. The gas partial pressure control assembly includes a cooling surface for condensation of the gas; and a movable shield configured to adjust the fluid path from the vacuum processing chamber to the cooling surface.

According to still another aspect of the present disclosure, a method of controlling partial pressure of a gas in a vacuum processing chamber is provided. The method includes a cooling surface for condensation of the gas; and adjusting a fluid path within the vacuum processing chamber with a movable shield.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 shows a schematic view of a vacuum processing system for deposition of a material on a substrate according to embodiments of the present disclosure;

FIG. 2 shows a schematic view of a vacuum processing apparatus for deposition of a material on a substrate according to embodiments of the present disclosure;

FIG. 3 shows a schematic view of a portion of a gas partial pressure control assembly having e.g. a driving motor for adjusting a movable shield inside the vacuum processing chamber according to embodiments described herein; and

FIG. 4 shows a flow chart of a method for water vapor partial pressure adjustment during deposition of a material on a substrate according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Generally, only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

Embodiments of the present disclosure provide a vacuum processing apparatus and a vacuum processing system. The cooling surface, for example, the cooling surface of the cryogenic system is provided to reduce the partial pressure of a gas, for example, the partial pressure of water vapor. Embodiments of the present disclosure enhance the controllability of pumping speed and enable a stable gas partial pressure, for example, a stable partial pressure of water vapor.

In the following, reference will be made to controlling the partial pressure of water vapor. However, embodiments of the present disclosure can similarly control the partial pressure of other gases.

The term “substrate” as used herein shall also embrace flexible substrates such as a web or a foil. The embodiments described herein can be utilized for deposition of materials on large area substrates, e.g., for display manufacturing. For instance, a large area substrate can be GEN 4.5, which corresponds to a surface area of about 0.67 m² (0.73×0.92 m), GEN 5, which corresponds to a surface area of about 1.4 m² (1.1 m×1.3 m), GEN 7.5, which corresponds to a surface area of about 4.29 m² (1.95 m×2.2 m), GEN 8.5, which corresponds to a surface area of about 5.7 m² (2.2 m×2.5 m), or even GEN 10, which corresponds to a surface area of about 8.7 m² (2.85 m×3.05 m). Even larger generations such as GEN 11 and GEN 12 and corresponding surface areas can similarly be implemented.

Manufacturers of, for example, touch panels have broad and changing product portfolios with the need to adapt quickly to a fast-paced technological evolution. For example, indium tin oxide can be deposited in a vacuum processing apparatus for the manufacturing of displays. According to some embodiments, which can be combined with other embodiments described herein, indium tin oxide (ITO) film can be deposited by sputter system. Particularly, rotary cathode can be used in sputter system. To improve target exchange and system maintenance easiness, a “cathode door” design is adopted. According to some embodiments, which can be combined with other embodiments described herein, a cathode door can include a sealing body or sealing plate, which can be referred to as a sealing member, and a support for one or more sputter cathodes and can be coupled to a vacuum chamber of the vacuum processing apparatus to seal the vacuum chamber. The cathode door can be opened by moving the sealing body or sealing plate of the cathode door away from the vacuum chamber for providing access to a target of a sputter cathode.

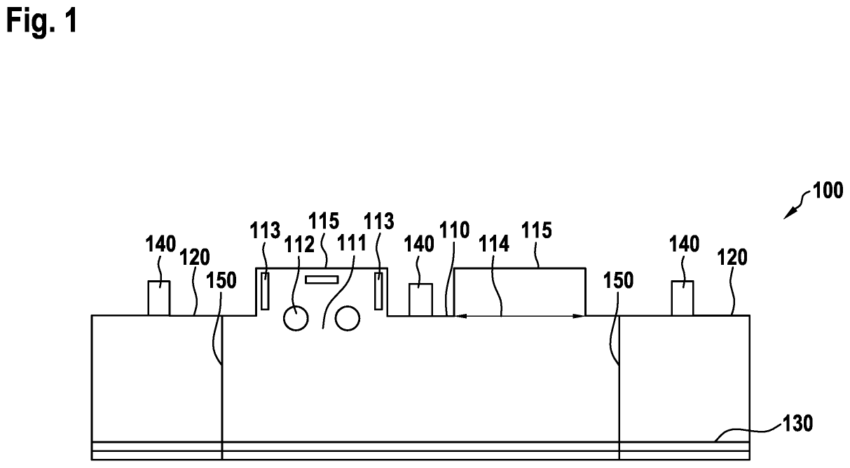

FIG. 1 shows a schematic view of a vacuum processing system 100, for example, for deposition of a material on a substrate. The vacuum processing system includes two or more vacuum chambers including a transfer chamber 120 and a vacuum processing chamber 110. The transfer chamber can be a transfer vacuum chamber. Furthermore, the vacuum processing system 100 includes a substrate support 130 extending at least through the transfer chamber 120 and the vacuum processing chamber 110. The transfer chamber 120 and the processing vacuum chamber 110 can be separated by a separation wall 150. The separation wall may include a gate valve. The gate valve may be opened and closed for transfer of the substrate or a carrier, respectively.

The vacuum processing system 100 includes at least one or more vacuum pumps 140, such as turbo molecular pumps, oil diffusion pumps, ion getter pumps, scroll pumps, or any other suitable vacuum pump. The vacuum processing system 100 includes one or more openings 114. The openings can be sealed with a sealing member 115. The sealing member 115 can be included in a vacuum door, vacuum gate or any other detachable sealing body or sealing plate. An atmosphere in a vacuum chamber can be controlled, for example, individually controlled, by generating a technical vacuum with vacuum pumps 140.

According to embodiments, which can be combined with other embodiments described herein, a “vacuum processing chamber” may be understood as a vacuum chamber in which a processing device for processing a substrate is arranged. The processing device may be understood as any device used for processing a substrate. For example, the processing device may include a deposition source for depositing a layer onto the substrate. Accordingly, the vacuum processing chamber or a vacuum processing apparatus including a deposition apparatus e.g. a deposition source or a deposition source assembly may also be referred to as a vacuum deposition chamber, respectively. The vacuum processing chamber may be a physical vapor deposition (PVD) chamber or may also be a chemical vapor deposition (CVD) chamber.

The vacuum processing chamber 110 includes a processing area 111, and a deposition apparatus 112 within the processing area 111. The deposition apparatus can, for example, include one or more cathodes having targets of the material to be deposited on the substrate. The cathodes can be rotatable cathodes with a magnetron therein. As an example, the cathodes are connected to an AC power supply or a DC power supply, such that the cathodes can be biased in an alternating manner. As an example, the deposition source can include a rotary cathode (DC ITO, DC Al, DC MoNb, MF SiO2, MF IGZO).

The vacuum processing chamber 110 includes one or more cooling surfaces 113. The one or more cooling surfaces can be provided in the cathode door. As described above, the cathode door can include the sealing member 115. The deposition apparatus 112 can be coupled to the sealing member, as “cathode door”, with a holder. The cathode door can further include the cooling surface 113.

A cryogenic refrigeration system may be provided in a vacuum processing apparatus. However, a cryogenic refrigeration system as such may either be turned on or turned off. Additionally or alternatively, a cryogenic refrigeration system may be provided remotely from the one or more deposition sources. Embodiments of the present disclosure provide a cooling surface, such as a highly efficient cryo-chiller, and a movable shielding. Accordingly, the partial pressure of the gas, for example, the partial pressure of water vapor can be adjusted. For example, the water partial pressure can be fine-tuned and/or water partial pressure manipulation in a wide range is enabled. According to some embodiments, which can be combined with other embodiments described herein, the cooling surface, for example, the surface area of cryo-coils, can be provided in the process chamber. Particularly, the cooling surface can be provided adjacent to the processing area. The cooling surface can be provided within the cathode door, i.e. can be supported by the cathode door and/or the sealing member 115. Having a cooling surface coupled with the cathode door and/or the sealing member 115, can maximize the water vapor pumping speed behind the shields and may, for example, prevent the material from being coated on the cooling surface.

Embodiments of the present disclosure refer to adjustment or control of a partial pressure of the gas, for example, the partial pressure of water vapor. As water vapor partial pressure is reduced in the vacuum chamber, reference can be made to “water pumping”. Accordingly, embodiments provide an improved water pumping efficiency, particularly during deposition of a layer on a substrate. Additionally or alternatively, embodiments provide control of the water pumping rate.

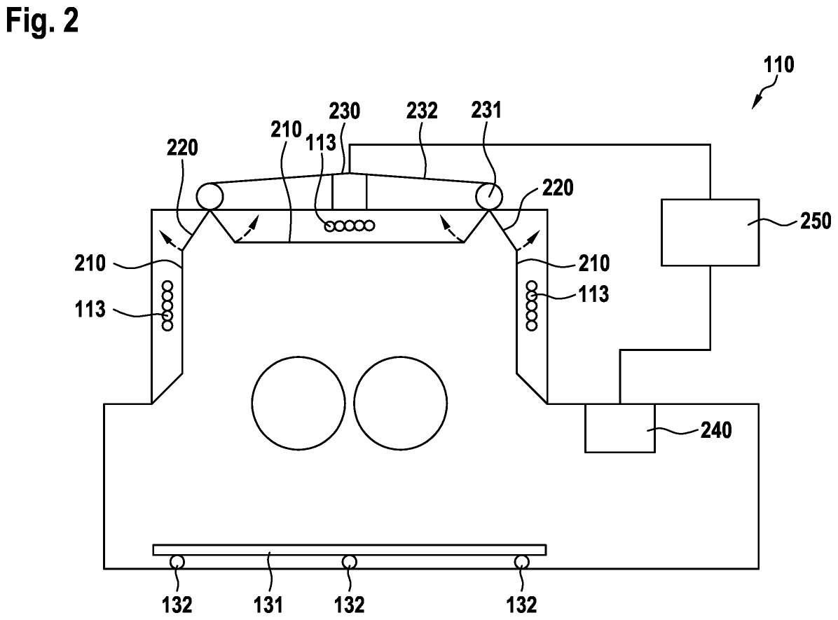

FIG. 2 shows a schematic view of a vacuum processing chamber 110. FIG. 2 shows a substrate 131 to be processed and at least one substrate holder 132 coupled with a substrate support. The vacuum processing chamber 110 includes at least a deposition apparatus 112 within the processing area 111. According to some embodiments, the deposition apparatus can be coupled to the sealing member 115 via a holder (not shown in FIG. 2). The substrate support 130 is configured for transporting or conveying the substrate or a first carrier on which the substrate is disposed, through the one or more vacuum chambers. According to some embodiments, which can be combined with other embodiments described herein, the substrate support provides a transportation path. The transportation path is provided through the processing system For example, the transportation system can be a roller based linear transportation system or can be a transportation system including a magnetic levitation system with a plurality of magnetic levitation boxes and magnetic drives.

The vacuum processing chamber 110 includes one or more cooling surfaces 113. The one or more cooling surfaces can be provided adjacent to the processing area 111. According to some embodiments, the processing apparatus provides the cooling surfaces coupled with the sealing member 115. The cooling surface 113 can be, for example, a pipe surface of a cryocoil cooler or a cooling surface of another cooling device or refrigerator assembly. For example, a Polycold Gas Chiller can be provided. Unlike cryopumps which only have small surface area to trap e.g. water, Polycold cryocoil surface can be up to 1 m² or more or even up to 2 m² or more. Ultra-law gas partial pressure can be reached.

The vacuum processing chamber 110 can include one or more fixed shields 210 which can at least partially surround the cooling surface 113. Furthermore, the vacuum processing chamber 110 includes one or more movable shields between the cooling surface and the processing area. The movable shields 220 can be blinder-type, flapping-type, stepper type, rotary type shield or any other movable shields. FIG. 2 shows the exemplary rotary type shield.

The movable shields provide an enclosed cooling area in a closed position. In an open position, the movable shields provide a fluid path between the cooling area and processing area inside the vacuum processing chamber. The cooling surface causes condensation of the gases with higher boiling point such as water vapor, alcohol, ammonia. Consequently, the gas partial pressure inside the vacuum processing chamber decreases. Therefore, adjusting the fluid communication between the cooling surface and processing area leads to a change in gas partial pressure inside the vacuum processing chamber. The fluid path between the cooling area and the processing area can provide the pumping of water vapor in the processing area.

FIG. 2 exemplarily shows a rotary type moving shield 220 which can be drivable with a motor 230. The exemplary rotary type moving shield 220 has a shield surface rotatable about a shaft (not shown in FIG. 2). The shaft can be coupled to a holder on at least one side. The shaft can be coupled with a feedthrough.

The vacuum processing chamber 110 includes plurality of sensors 240 (such as a thermometer, a pressure sensor, a humidity sensor, residual gas sensor) within the vacuum processing chamber 110, in order to read and record the vacuum processing chamber's properties and provide the necessary data for monitoring and controlling the vacuum properties.

Vacuum processing system 100 can include a controller 250, for example, outside the vacuum processing system 100, for example in atmosphere pressure. The controller 250 is in communication with a plurality of sensors 240 and the motor 230. The communication between the controller 250 and the plurality of sensors 240, and the controller 250 and the motor 230 can be via wires or wireless communication. The controller 250 can be a PLC (programmable logic controller) or any other controller including a CPU, a memory and user interface. The controller can actuate the rotary type moving shield 220 or another moving shield to adjust and/or control the fluid path between the deposition area and the cooling surface. Accordingly, the gas partial pressure can be adjusted by actuation of the moving shield, which can be controlled by the controller 250.

The disclosure provides a gas partial pressure control assembly coupled with the vacuum processing apparatus. The gas partial pressure control assembly includes a cooling surface 113 for condensation of gas and one or more movable shields in order to adjust the fluid path between the processing area and the cooling surface 113. According to some embodiments, also one or more fixed shields can be provided. The gas partial pressure control assembly includes a motor 230, a gearbox 231 (e.g. a planet gear or any suitable gear) coupled with the movable shields. The gearbox can be coupled with the motor by a belt 232. The motor, the belt and the gearbox can be located outside the vacuum processing chamber (e.g. atmosphere pressure). A protective cover, which is not shown in FIG. 2, is designed to avoid human injury. The gas partial pressure control assembly includes one or more holders and one or more support plates. The gas partial pressure assembly includes a controller 250 outside the vacuum chamber in communication with the plurality of sensors 240 inside the vacuum chamber and the motor 230.

The controller 250 can adjust the movable shield's opening position. For example, the controller 250 can control the rotation of motor 230 and drive the angle of the planet gear 231 which will motivate the rotary shield 220 through feedthrough. The rotary shield's opening angle can control the water pump speed or the amount of fluid communication and gas condensation on the cooling surface and consequently can control gas partial pressure inside the vacuum processing chamber.

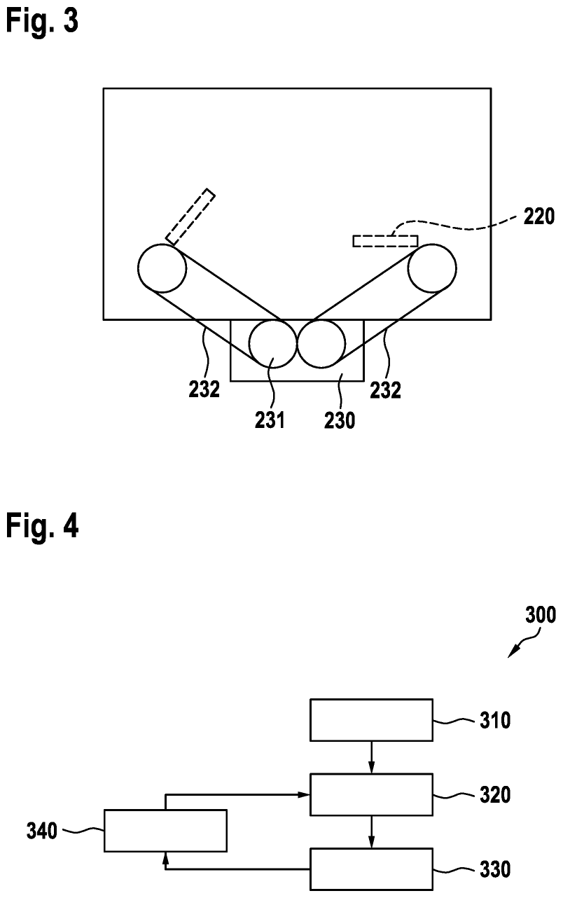

FIG. 3 shows an exemplary schematic view of a part of the gas partial pressure control assembly. FIG. 3 shows a motor 230 coupled to the gearbox 231 via a belt 232. A support plate is provided outside the motor 230 coupled via the belt 232 to the gearbox 231 and feedthrough (not shown in FIG. 3) and the rotary shield 220. The rotary shields are moving about the shaft (not shown in FIG. 3). The shaft is coupled via feedthrough and belt to the gearbox and motor, respectively.

Embodiments of the present disclosure enable the user to adjust water pumping speed or pumping speed of another process gas by controlling the movement of one or more movable shields e.g. with the motor controlled by the controller. For example, the current disclosure enables the user to control and maintain a stable water vapor level during processing inside the vacuum chamber.

A user or an automated system may remotely tune the gas partial pressure inside the vacuum chamber, while the vacuum is sealed and performing substrate processing. Furthermore, the opening of the shielding can be controlled, e.g. by means of a planet gear and a motor. Embodiments of the present disclosure optimize the cooling system pumping efficiency and stabilize the gas partial pressure in a predefined range.

According to some embodiments, the vacuum processing system can have a modular design such as having detachable vacuum transition chambers 120, a vacuum processing chamber 110 and a vacuum track. Furthermore, the vacuum sealing member 115 can be considered as a module. Modularity offers benefits such as reduction in cost, interoperability, flexibility in design, non-generationally constrained augmentation or updating, and exclusion.

FIG. 4 shows a flowchart of a method 300 for controlling the gas partial pressure inside the vacuum chamber 110. The method includes a cooling surface for condensation of the gas, as indicated by operation 310. The method includes adjusting a fluid path within the vacuum processing chamber with a movable shield, as indicated by operation 320.

According to some embodiments, the method includes operation of at least one sensor 240 from the plurality of sensors (e.g. humidity sensor, thermometer, pressure sensor, residual gas sensor) inside the vacuum processing chamber 330, and operation of a controller 250 (e.g. PLC controller) outside the vacuum processing chamber 340. The controller is in communication with the plurality of sensors and in communication with the motor. The controller can adjust the position of the movable shields by controlling the motor.

According to embodiments of the present disclosure, controlling of pumping speed, for example, water pumping speed, enables the user to control the gas partial pressure, for example water vapor partial pressure, inside the vacuum processing chamber by adjusting the fluid path between the cooling area and vacuum processing chamber.

According to some embodiments, which can be combined with other embodiments, the method includes controlling of a gas partial pressure wherein the gas is water vapor.

The method of controlling the gas partial pressure inside the vacuum chamber includes adjusting the movable shields to be in one of the three positions, open, closed and partially open. The minimum amount of water vapor is removed from the vacuum processing chamber when the movable shields are in a closed position and the fluid path between the cooling area and vacuum processing chamber is closed. The cooling surface can remove the maximum amount of water vapor from the vacuum processing chamber when the movable shields are in a fully open position and the fluid path between the cooling area and vacuum processing chamber is open.

The cooling surface can remove an amount of water vapor, e.g. a predetermined amount of water vapor, from the vacuum processing chamber when the movable shields are in a predetermined position, e.g. in a position between maximum open and closed position adjusted by the controller. The position of the movable shield can be controlled, e.g. with a feedback control loop, such as a PLC controller.

The method includes that the controller 250 receives the data from inside the vacuum chamber, e.g. by one or more plurality of sensors 240, for example through wire connection or wireless communication. The controller saves and processes the data. The controller includes a user interface which enables the user to program the controller or alternatively manually use the controller.

The method includes the controller 250 being in communication with the motor 230, through wire connection or wireless communication. The controller 250 can control the opening of the movable shields by means of controlling the motor 230.

The method includes receiving and processing data from sensor(s) 240. The controller can be programmed to control the opening of the movable shields. For example, the controller can read and check if the water vapor partial pressure inside the vacuum chamber is within the predefined range or not, and accordingly adjust the opening of the movable shields in order to keep or reach the water vapor partial pressure within the predefined range. The predefined range of water vapor pressure can be set or defined by the user for the controller.

According to some embodiments, the disclosure provides a method for keeping water partial pressure within the desired range, in order to provide optimum quality of deposition.

According to embodiments of the present disclosure, the controller 250 and the motor 230 and gearbox 231 are located outside the vacuum processing chamber. The cooling surface and the fixed and movable shields and shield holders are located within the vacuum processing chamber. The motor motivates the gear with a belt through HMI, accurately adjusting the opening of the movable shields.

According to embodiments of the present disclosure, the method enables the user to finely control and adjust the gas partial pressure inside the vacuum processing chamber, during the procedure of processing the substrate. The method enables the user to accurately control the gas partial pressure inside the vacuum chamber remotely while the vacuum chamber is closed.

In view of the above, a vacuum processing apparatus for deposition of a material on a substrate and a method for depositing a material on a substrate that overcome at least some of the problems in the art are needed, for example, to keep the water vapor partial pressure steady within the predefined range in order to improve the deposition quality.

While the foregoing is directed to embodiments of the disclosure, other and further embodiments of the disclosure may be devised without departing from the basic scope thereof, and the scope thereof is determined by the claims that follow.

1. A vacuum processing apparatus, comprising:
a vacuum chamber comprising a processing area;
a deposition apparatus within the processing area of the vacuum chamber;
a cooling surface inside the vacuum chamber; and
one or more movable shields between the cooling surface and the processing area.

2. The vacuum processing apparatus according to claim 1, wherein the vacuum chamber has an opening, the vacuum processing apparatus further comprising:
a sealing member configured to seal the opening, the cooling surface is being coupled to the sealing member, the sealing member comprising:
a holder for the deposition apparatus.

3. A vacuum processing apparatus, comprising:
a vacuum chamber having an opening; and
a sealing member configured to seal the opening, the sealing member comprising:
a holder for a deposition apparatus; and
a cooling surface coupled to the sealing member.

4. The vacuum processing apparatus according to claim 3, wherein the vacuum chamber comprises a processing area, the deposition apparatus being within the processing area of the vacuum chamber, and the cooling surface being inside the vacuum chamber, the vacuum processing apparatus further comprising:
one or more movable shields between the cooling surface and the processing area.

5. The vacuum processing apparatus according to claim 1, further comprising:
one or more fixed shields at least partially surrounding the cooling surface.

6. The vacuum processing apparatus according to claim 5, wherein the one or more fixed shields and the one or more movable shields provide an enclosure for the cooling surface when the one or more movable shields are in a closed position.

7. The vacuum processing apparatus according to claim 5, wherein the one or more fixed shields and the one or more movable shields provide a fluid path between the cooling surface and the processing area when the one or more movable shields are in an open position.

8. The vacuum processing apparatus according to claim 7, wherein the fluid path is adjustable by adjusting an angle or a position of the one or more movable shields in the open position.

9. The vacuum processing apparatus according to claim 1, wherein the cooling surface is the surface of a plurality of pipes.

10. The vacuum processing apparatus according to claim 1, wherein the cooling surface is a cryogenic surface of a cryogenic cooling apparatus.

11. The vacuum processing apparatus according to claim 1, further comprising:
at least one vacuum pump in fluid communication with the vacuum chamber, wherein the vacuum pump is selected from the group consisting of: turbo molecular pumps, oil diffusion pumps, ion getter pumps, scroll pumps.

12. A vacuum processing system comprising:
a vacuum processing, comprising:
a vacuum chamber comprising a processing area;
a deposition apparatus within the processing area of the vacuum chamber;
a cooling surface inside the vacuum chamber; and
one or more movable shields between the cooling surface and the processing area;
the vacuum processing system, further comprising:
at least one transfer chamber.

13. The vacuum processing system of claim 12, further comprising:
a substrate support for transporting a substrate through the at least one transfer chamber into the vacuum processing apparatus.

14. A gas partial pressure control assembly for a vacuum processing chamber, comprising:
a cooling surface for condensation of the gas; and
a movable shield configured to adjust the fluid path from the vacuum processing chamber to the cooling surface.

15. The gas partial pressure control assembly of claim 14, wherein the movable shield is a rotary type moving shield.

16. The gas partial pressure control assembly of claim 15, further comprising:
a motor; and
at least one of: a shield surface, a gear box, a belt, a holder, and a support plate.

17. The gas partial pressure control assembly of claim 15, wherein the movable shield is rotatable around a shaft by means of a motor.

18. A method of controlling partial pressure of a gas in a vacuum processing chamber, comprising:
cooling a surface for condensation of the gas; and
adjusting a fluid path within the vacuum processing chamber with a movable shield.

19. The method of claim 18, comprising:
at least one humidity sensor; and
a controller coupled to the at least one humidity sensor.

20. The method of claim 18, wherein the gas is water vapor.
